(19) United States
(12) Patent Application Publication
(10) Pub. No.: US 2012/0049179 A1
(43) Pub. Date: Mar. 1, 2012

(54) GROUP-III NITRIDE-BASED LIGHT EMITTING DEVICE HAVING ENHANCED LIGHT EXTRACTION EFFICIENCY AND MANUFACTURING METHOD THEREOF

(75) Inventors: Ming-teng KUO, Taoyuan (TW); Jang-ho Chen, Taoyuan (TW); Ching-hwa Chang Jean, Taoyuan (TW)

(73) Assignee: WALSIN LIHWA CORPORATION, Taoyuan (TW)

(21) Appl. No.: 12/862,802

(22) Filed: Aug. 25, 2010

(51) Int. Cl. H01L 33/02; H01L 33/16; H01L 33/00

(52) U.S. Cl. 257/43; 438/29; 257/94; 257/77; 257/76; 257/103; 257/98; 257/E33.013; 257/E33.005

(57) ABSTRACT

A method for enhancing light extraction efficiency of a group-III nitride-based light emitting device is disclosed. By roughening a n-type group-III nitride-based cladding layer or an undoped group-III nitride-based layer, a reflecting layer is formed. Because of gaps on the roughened surface, total internal reflection occurs, and light beams can be reflected back to a top surface of the light emitting device. Thus, the light extraction efficiency can be increased, and more light beams can be collected in a desired direction.

### FIELD OF THE INVENTION

The present invention relates to a light emitting device having enhanced light extraction efficiency, and more particularly, to a group-III nitride-based light emitting device, such as a GaN light emitting device, partially roughened during epitaxial growth.

### BACKGROUND OF THE INVENTION

Group-III nitride-based semiconductors are direct-transition-type semiconductors exhibiting a wide range of emission spectra from UV to red light when used in a device such as light-emitting diodes (LEDs) and laser diodes (LDs).

When a light-emitting device has higher external quantum efficiency (the number of photons extracted to the outside/the number of injected carriers), the less power consumption can be achieved. The external quantum efficiency can be raised by increasing the light extraction efficiency (the number of photons extracted to the outside/the number of emitted photons) or the internal quantum efficiency (the number of emitted photons/the number of injected carriers). The increase of the internal quantum efficiency means the decrease of the energy of the heat converted from the electricity given to the light-emitting element. Therefore, it is considered that the increase of the internal quantum efficiency not only reduces the power consumption but also suppresses the lowering of the reliability due to the heating.

The extraction efficiency of an LED can be much improved by either growing or mechanically bonding the lower confining layer upon a transparent substrate rather than an absorbing substrate. The extraction efficiency of a transparent substrate LED is reduced by the presence of any layers in the LED that have an energy gap equal to or smaller than that of the light-emitting layers. This is because some of the light that is emitted by the active layer passes through the absorbing layers before it exits the LED. These absorbing layers are included because they reduce the number of threading dislocations or other defects in the active layer or are used to simplify the LED manufacturing process. Another effect is to reduce band offsets at hetero-interfaces, which lower the voltage that must be applied to the contacts in order to force a particular current through the diode. Because the absorbing layers tend to absorb shorter-wavelength light more effectively than longer-wavelength light, LEDs that emit at 590 nm suffer a greater performance penalty due to the presence of these layers than LEDs that emit at 640 nm.

Another means to improve the extraction efficiency of an LED is to roughen the light emitting diode. Please refer to FIG. 1. A conventional light emitting diode is shown. When a current is applied to the p and n-contacts, light beams are emitted from the MQW (multiple quantum well). In this case, the upward light beams will be utilized. In order to increase light extraction of the light emitting diode, the top surface of the light emitting diode on which the p and n-contacts are formed is roughened after the whole light emitting diode structure is manufactured. The roughening process changes the extraction angles of the light beams emitted out of the top surface of the light emitting diode for increasing light extraction. However, the light beams emitting downwards can not be used and will be absorbed by the absorbing layers below the MQW. Another situation is shown in FIG. 2. A patterned sapphire substrate is used. It can help release more light beams out of the light emitting diode from the patterned sapphire substrate. Nevertheless, this method has some defects. For example, portions of light beams will be absorbed before they arrive at the substrate. Light extraction efficiency can not be increased significantly.

In addition to roughening means, reflectors on one side of light emitting diode are often applied, such as Bragg reflector. Please refer to FIG. 3. As shown in U.S. Pat. No. 6,643,304, a Bragg reflector composes layers of interleaved materials having different refraction indexes. The window layers are on the top of the light emitting diode, and the Bragg reflector is formed on the bottom, vice versa. In practice, the Bragg reflector works well for reflecting light to increase light extraction efficiency. However, the Bragg reflector needs many processes to manufacture. It is hard to reduce cost for a light emitting diode with a Bragg reflector layer.

No matter whether a patterned sapphire substrate or a Bragg reflector layer is used, it is definite that emitted effective light beams are increased. However, there is still one problem which is unsolved. Namely, there are still light beams absorbed by the absorbing layers before they reach the top layer of the light emitting diode or the Bragg reflector layer. If the aforementioned problem is solved, light extraction efficiency can be further improved.

### SUMMARY OF THE INVENTION

Accordingly, the prior arts are limited by the above problems. It is an object of the present invention to provide a group-III nitride-based light emitting device having enhanced light extraction efficiency and a manufacturing method thereof.

In accordance with an aspect of the present invention, a method for enhancing light extraction efficiency of a group-III nitride-based light emitting device includes the steps of: a) providing a substrate; b) forming an undoped group-III nitride-based layer on the substrate; c) roughening the undoped group-III nitride-based layer; d) growing a n-type group-III nitride-based cladding layer, an active region, and a p-type group-III nitride-based cladding layer on the undoped group-III nitride-based layer in sequence; and e) providing a p-contact and a n-contact on the p-type group-III nitride-based cladding layer and the n-type group-III nitride-based cladding layer, respectively. A number of gaps are formed between the undoped group-III nitride-based layer and the n-type group-III nitride-based cladding layer.

In accordance with another aspect of the present invention, a method for enhancing light extraction efficiency of a group-III nitride-based light emitting device includes the steps of: a) providing a substrate; b) forming a first undoped group-III nitride-based layer on the substrate; c) roughening the first undoped group-III nitride-based layer; d) growing a second undoped group-III nitride-based layer, a n-type group-III nitride-based cladding layer, an active region, and a p-type group-III nitride-based cladding layer on the first undoped group-III nitride-based layer in sequence; and e) providing a p-contact and a n-contact on the p-type group-III nitride-based cladding layer and the n-type group-III nitride-based cladding layer, respectively. A number of gaps are formed between the first undoped group-III nitride-based layer and the second undoped group-III nitride-based cladding layer.

In accordance with still another aspect of the present invention, a method for enhancing light extraction efficiency of a group-III nitride-based light emitting device includes the steps of: a) providing a substrate; b) forming an undoped group-III nitride-based layer on the substrate; c) forming a first n-type group-III nitride-based cladding layer on the undoped group-III nitride-based layer; d) roughening the first n-type group-III nitride-based cladding layer; e) growing a second n-type group-III nitride-based cladding layer, an active region, and a p-type group-III nitride-based cladding layer on the first n-type group-III nitride-based cladding layer in sequence; and e) providing a p-contact and a n-contact on the p-type group-III nitride-based cladding layer and the second n-type group-III nitride-based cladding layer, respectively. A number of gaps are formed between the first n-type group-III nitride-based cladding layer and the second n-type group-III nitride-based cladding layer.

Preferably, the substrate is a sapphire substrate, a silicon carbide substrate, a GaN substrate, a ZnO substrate, or a GaAs substrate.

Preferably, the roughening process is performed by dry etching or wet etching.

Preferably, the dry etching is reactive ion etching, inductively coupled plasma etching or high density plasma etching.

In accordance with the aspect of the present invention, a group-III nitride-based light emitting device having enhanced light extraction efficiency includes: a substrate; an undoped group-III nitride-based layer having a roughened surface formed on the substrate; a n-type group-III nitride-based cladding layer, an active region, and a p-type group-III nitride-based cladding layer grown on the undoped group-III nitride-based layer in sequence; and a p-contact and a n-contact provided on the p-type group-III nitride-based cladding layer and the n-type group-III nitride-based cladding layer, respectively. A number of gaps are formed between the undoped group-III nitride-based layer and the n-type group-III nitride-based cladding layer.

In accordance with the another aspect of the present invention, a group-III nitride-based light emitting device having enhanced light extraction efficiency includes: a substrate; a first undoped group-III nitride-based layer having a roughened surface formed on the substrate; a second undoped group-III nitride-based layer, a n-type group-III nitride-based cladding layer, an active region, and a p-type group-III nitride-based cladding layer grown on the first undoped group-III nitride-based layer in sequence; and a p-contact and a n-contact provided on the p-type group-III nitride-based cladding layer and the n-type group-III nitride-based cladding layer, respectively. A number of gaps are formed between the first undoped group-III nitride-based layer and the second undoped group-III nitride-based cladding layer.

In accordance with the still another aspect of the present invention, a group-III nitride-based light emitting device having enhanced light extraction efficiency includes: a substrate; an undoped group-III nitride-based layer formed on the substrate; a first n-type group-III nitride-based cladding layer having a roughened surface formed on the undoped group-III nitride-based layer; a second n-type group-III nitride-based cladding layer, an active region, and a p-type group-III nitride-based cladding layer grown on the first n-type group-III nitride-based cladding layer in sequence; and a p-contact and a n-contact provided on the p-type group-III nitride-based cladding layer and the second n-type group-III nitride-based cladding layer, respectively. A number of gaps are formed between the first n-type group-III nitride-based cladding layer and the second n-type group-III nitride-based cladding layer.

Preferably, the substrate is a sapphire substrate, a silicon carbide substrate, a GaN substrate, a ZnO substrate, or a GaAs substrate.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 shows a prior art light emitting device having a roughened top surface;

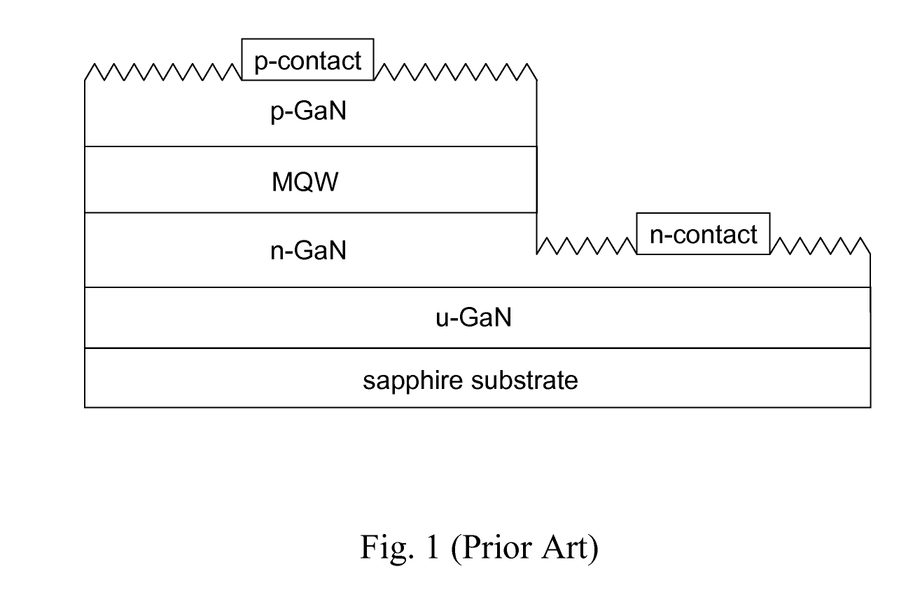

FIG. 2 shows a prior art light emitting device having a roughened substrate;

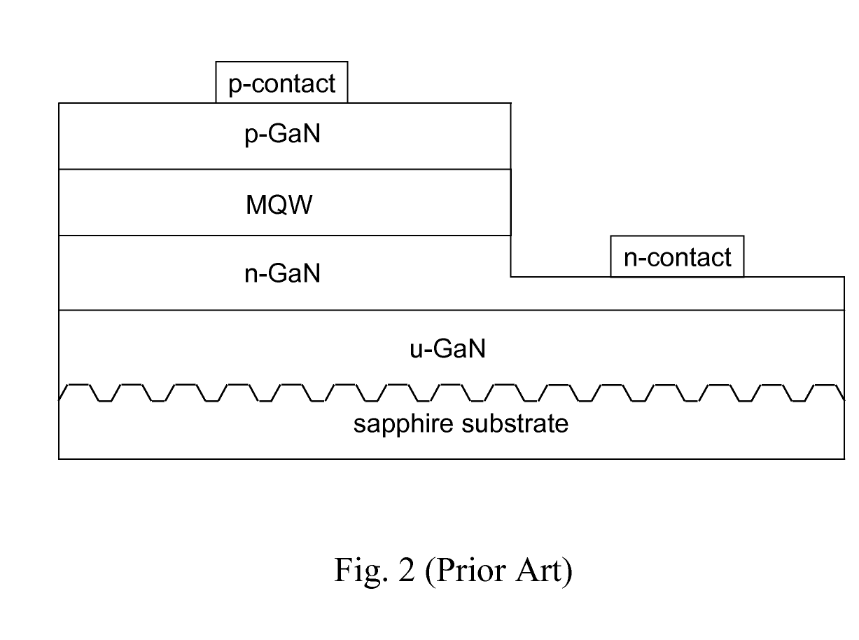

FIG. 3 shows a prior art light emitting device having a Bragg reflector layer for reflecting light beams;

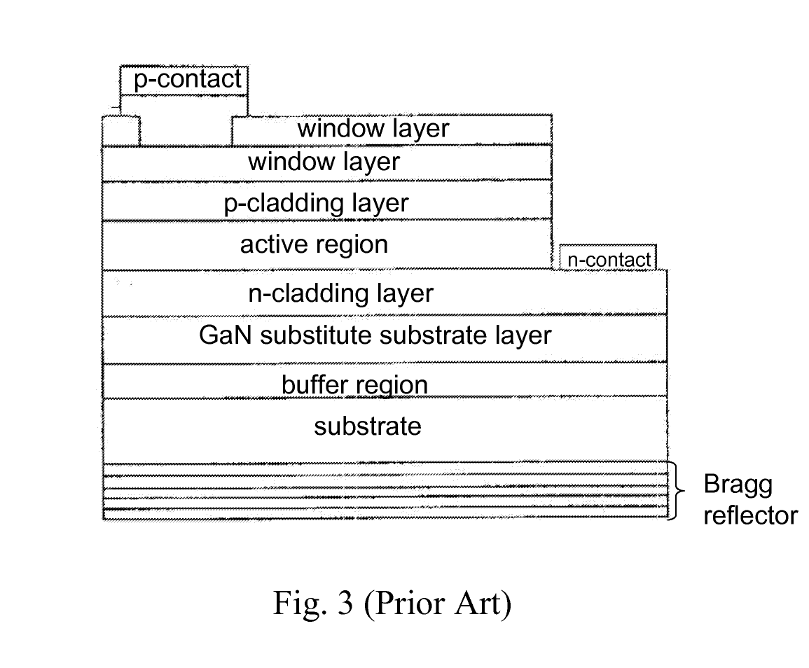

FIG. 4 is a diagram showing a light emitting device of a first embodiment of the present invention;

FIG. 5 shows how the light beams are reflected in the first embodiment; and

FIG. 6 is a diagram showing a light emitting device of a second embodiment of the present invention.

### DETAILED DESCRIPTION OF THE PREFERRED EMBODIMENTS

The present invention will now be described more specifically with reference to two embodiments. It is to be noted that the following descriptions of preferred embodiments of this invention are presented herein for purpose of illustration and description only; it is not intended to be exhaustive or to be limited to the precise form disclosed.

### First Embodiment

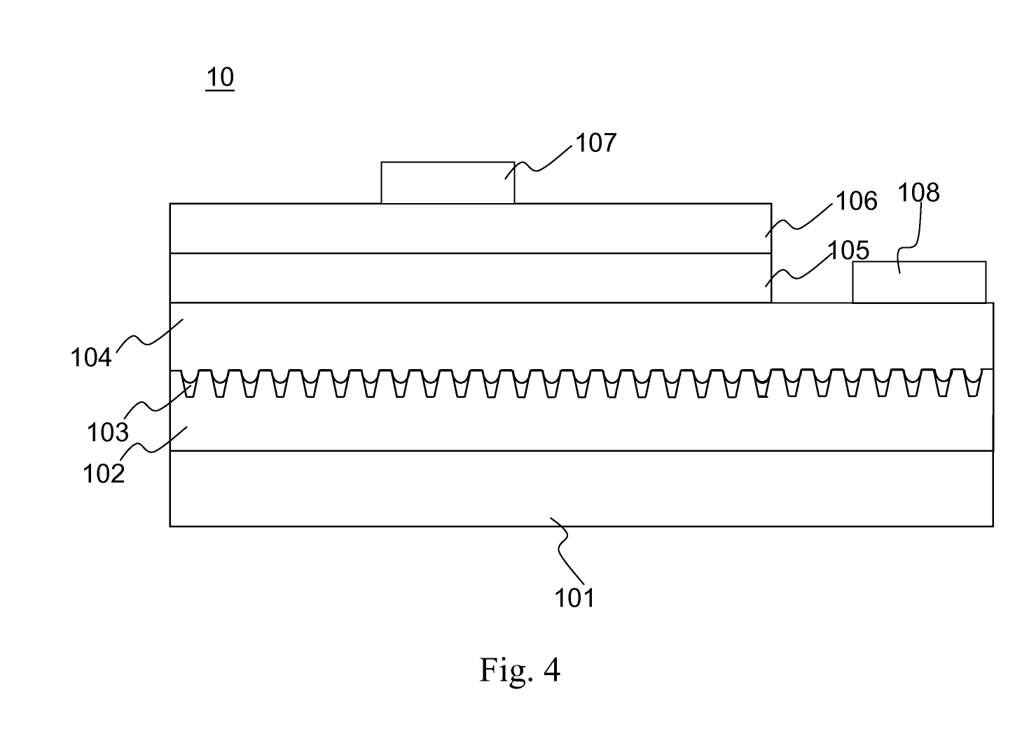

Please refer to FIG. 4. A first embodiment is illustrated. A light emitting diode 10 is manufactured according to the present invention. The light emitting diode 10 is mainly composed of group-III nitride components. First, a substrate 101 is formed. The substrate 101 is a sapphire substrate. Then, an undoped GaN (u-GaN) layer 102 is formed on the substrate 101. The u-GaN layer 102 can be roughened by a dry etching process or a wet etching process. Preferably, the dry etching process is reactive ion etching. In practice, inductively coupled plasma etching or high density plasma etching can also be used. The u-GaN layer 102 has a roughened top surface.

Generally, it is easy to roughen the surface of the u-GaN layer 102 and control the roughness of the surface. Intervals between two adjacent peaks of the roughened surface can be smaller than 10 μm. Next, an n-GaN layer 104 is epitaxially grown on the u-GaN layer 102. The small intervals result in formation of gaps 103 between the u-GaN layer 102 and the n-GaN layer 104.

After the n-GaN layer 104 is completed, an active region 105 and a p-GaN layer 106 are formed upon the n-GaN layer 104 in sequence. The active region 105 is a Multiple Quantum Well (MQW) for generating light beams. The p-GaN layer 106 can emit the light beams out of the light emitting diode 10. Finally, a p-contact 107 and a n-contact 108 are connected to the p-GaN layer 106 and the u-GaN layer 102, respectively, for providing power.

Please note that the roughened surface is between the u-GaN layer 102 and the n-GaN layer 104. In other words, the roughening process is executed after the u-GaN layer 102 is formed. The substrate 101 is not limited to a sapphire substrate. It can be a silicon carbide substrate, a GaN substrate, a ZnO substrate, or a GaAs substrate.

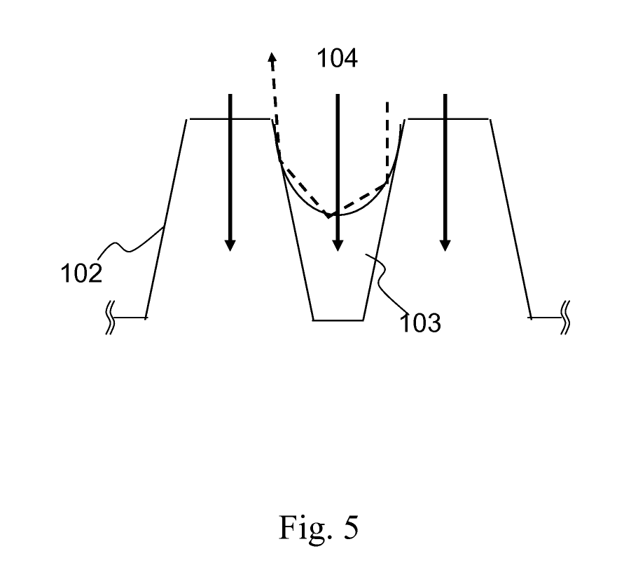

The gaps 103 are formed because the intervals are so small that the epitaxial growing process of any layer upon the uneven surface will not fill the intervals completely. Please see FIG. 5. Solid arrows represent light penetrating through the u-GaN layer 102 and the n-GaN layer 104 without being refracted. A dashed arrow is an example of a light beam totally reflected, since the refraction index of air in the gap 103 is around 1 and that of the n-GaN layer 104 is around 2˜4. Light beams will be reflected back to the n-GaN layer 104. Hence, number of effective light beams emitting from the light emitting diode 10 will be increased, thereby enhancing light extraction efficiency.

### Second Embodiment

According to the present invention, the roughened surface is not limited to an interface between two different layers. The roughening process can also be applied to two layers of the same material.

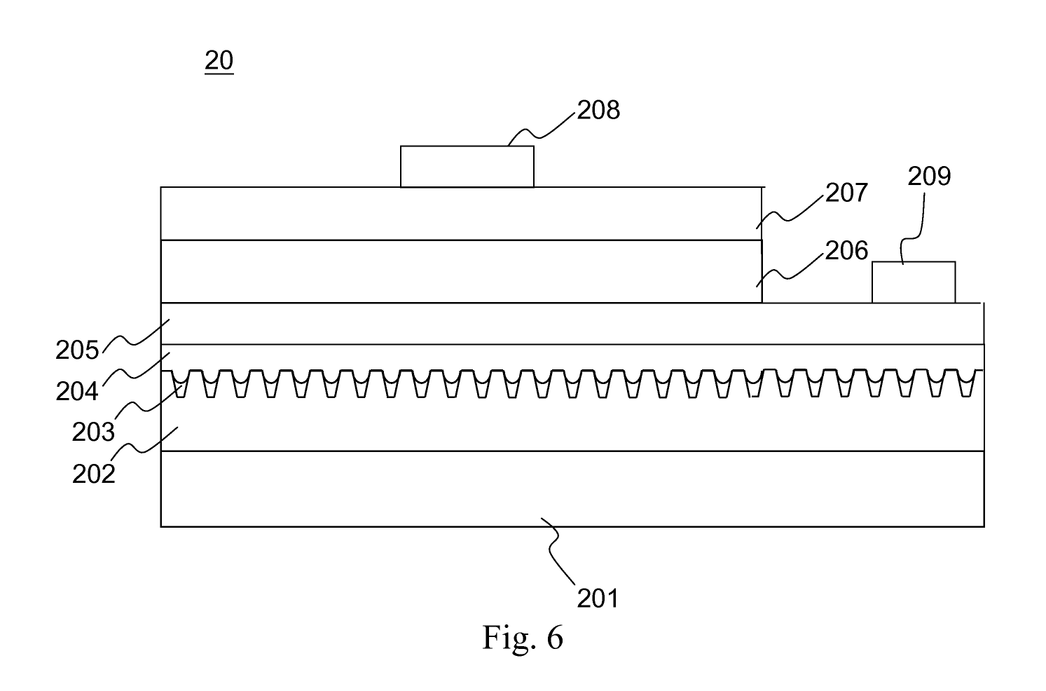

Please refer to FIG. 6. A second embodiment is illustrated. A light emitting diode 20 is manufactured according to the present invention. Like the one in the first embodiment, the light emitting diode 20 is mainly composed of group-III nitride components. First, a sapphire substrate 201 is formed. Then, a first u-GaN layer 202 is formed on the substrate 201. The first u-GaN layer 202 is roughened by a reactive ion etching process. Next, the same epitaxial process forms a second u-GaN layer 204. In this embodiment, the first u-GaN layer 202 and the second u-GaN layer 204 are substantially the same. The purpose of the roughening process is to form a number of gaps 203 therebetween.

After the second u-GaN layer 204 is completed, an n-GaN layer 205, an active region 206 and a p-GaN layer 207 are formed upon the u-GaN layer 204 in sequence. The active region 206 is also a Multiple Quantum Well (MQW) for generating photons. Finally, a p-contact 208 and a n-contact 209 are connected to the p-GaN layer 207 and the n-GaN layer 205, respectively, for providing power.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A method for enhancing light extraction efficiency of a group-III nitride-based light emitting device, comprising the steps of:
a) providing a substrate;
b) forming an undoped group-III nitride-based layer on the substrate;
c) roughening the undoped group-III nitride-based layer;
d) growing a n-type group-III nitride-based cladding layer, an active region, and a p-type group-III nitride-based cladding layer on the undoped group-III nitride-based layer in sequence; and
e) providing a p-contact and a n-contact on the p-type group-III nitride-based cladding layer and the n-type group-III nitride-based cladding layer, respectively;
wherein a plurality of gaps are formed between the undoped group-III nitride-based layer and the n-type group-III nitride-based cladding layer.

2. The method according to claim 1, wherein the substrate is a sapphire substrate, a silicon carbide substrate, a GaN substrate, a ZnO substrate, or a GaAs substrate.

3. The method according to claim 1, wherein the roughening process is performed by dry etching or wet etching.

4. The method according to claim 3, wherein the dry etching is reactive ion etching, inductively coupled plasma etching or high density plasma etching.

5. A method for enhancing light extraction efficiency of a group-III nitride-based light emitting device, comprising the steps of:
a) providing a substrate;
b) forming a first undoped group-III nitride-based layer on the substrate;
c) roughening the first undoped group-III nitride-based layer;
d) growing a second undoped group-III nitride-based layer, a n-type group-III nitride-based cladding layer, an active region, and a p-type group-III nitride-based cladding layer on the first undoped group-III nitride-based layer in sequence; and
e) providing a p-contact and a n-contact on the p-type group-III nitride-based cladding layer and the n-type group-III nitride-based cladding layer, respectively;
wherein a plurality of gaps are formed between the first undoped group-III nitride-based layer and the second undoped group-III nitride-based cladding layer.

6. The method according to claim 5, wherein the substrate is a sapphire substrate, a silicon carbide substrate, a GaN substrate, a ZnO substrate, or a GaAs substrate.

7. The method according to claim 5, wherein the roughening process is performed by dry etching or wet etching.

8. The method according to claim 7, wherein the dry etching is reactive ion etching, inductively coupled plasma etching or high density plasma etching.

9. A method for enhancing light extraction efficiency of a group-III nitride-based light emitting device, comprising the steps of:
a) providing a substrate;
b) forming an undoped group-III nitride-based layer on the substrate;
c) forming a first n-type group-III nitride-based cladding layer on the undoped group-III nitride-based layer;
d) roughening the first n-type group-III nitride-based cladding layer;
e) growing a second n-type group-III nitride-based cladding layer, an active region, and a p-type group-III nitride-based cladding layer on the first n-type group-III nitride-based cladding layer in sequence; and
e) providing a p-contact and a n-contact on the p-type group-III nitride-based cladding layer and the second n-type group-III nitride-based cladding layer, respectively;
wherein a plurality of gaps are formed between the first n-type group-III nitride-based cladding layer and the second n-type group-III nitride-based cladding layer.

10. The method according to claim 9, wherein the substrate is a sapphire substrate, a silicon carbide substrate, a GaN substrate, a ZnO substrate, or a GaAs substrate.

11. The method according to claim 9, wherein the roughening process is performed by dry etching or wet etching.

12. The method according to claim 11, wherein the dry etching is reactive ion etching, inductively coupled plasma etching or high density plasma etching.

13. A group-III nitride-based light emitting device having enhanced light extraction efficiency, comprising:
a substrate;
an undoped group-III nitride-based layer having a roughened surface formed on the substrate;
a n-type group-III nitride-based cladding layer, an active region, and a p-type group-III nitride-based cladding layer grown on the undoped group-III nitride-based layer in sequence; and
a p-contact and a n-contact provided on the p-type group-III nitride-based cladding layer and the n-type group-III nitride-based cladding layer, respectively;
wherein a plurality of gaps are formed between the undoped group-III nitride-based layer and the n-type group-III nitride-based cladding layer.

14. The group-III nitride-based light emitting device according to claim 13, wherein the substrate is a sapphire substrate, a silicon carbide substrate, a GaN substrate, a ZnO substrate, or a GaAs substrate.

15. A group-III nitride-based light emitting device having enhanced light extraction efficiency, comprising:
a substrate;
a first undoped group-III nitride-based layer having a roughened surface formed on the substrate;
a second undoped group-III nitride-based layer, a n-type group-III nitride-based cladding layer, an active region, and a p-type group-III nitride-based cladding layer grown on the first undoped group-III nitride-based layer in sequence; and
a p-contact and a n-contact provided on the p-type group-III nitride-based cladding layer and the n-type group-III nitride-based cladding layer, respectively;
wherein a plurality of gaps are formed between the first undoped group-III nitride-based layer and the second undoped group-III nitride-based cladding layer.

16. The group-III nitride-based light emitting device according to claim 15, wherein the substrate is a sapphire substrate, a silicon carbide substrate, a GaN substrate, a ZnO substrate, or a GaAs substrate.

17. A group-III nitride-based light emitting device having enhanced light extraction efficiency, comprising:
a substrate;
an undoped group-III nitride-based layer formed on the substrate;
a first n-type group-III nitride-based cladding layer having a roughened surface formed on the undoped group-III nitride-based layer;
a second n-type group-III nitride-based cladding layer, an active region, and a p-type group-III nitride-based cladding layer grown on the first n-type group-III nitride-based cladding layer in sequence; and
a p-contact and a n-contact provided on the p-type group-III nitride-based cladding layer and the second n-type group-III nitride-based cladding layer, respectively;
wherein a plurality of gaps are formed between the first n-type group-III nitride-based cladding layer and the second n-type group-III nitride-based cladding layer.

18. The group-III nitride-based light emitting device according to claim 17, wherein the substrate is a sapphire substrate, a silicon carbide substrate, a GaN substrate, a ZnO substrate, or a GaAs substrate.
